(19) United States
(12) Patent Application Publication
(10) Pub. No.: US 2026/0038577 A1
(43) Pub. Date: Feb. 5, 2026

(54) PROGRAMMABLE ARRAY SPACES

(71) Applicant: Micron Technology, Inc., Boise, ID (US)

(72) Inventors: Alec S. Wyen, Boise, ID (US); Rachael S. Skreen, Boise, ID (US)

(73) Assignee: Micron Technology, Inc., Boise, ID (US)

(21) Appl. No.: 19/263,271

(22) Filed: Jul. 8, 2025

Related U.S. Application Data
(60) Provisional application No. 63/677,285, filed on Jul. 30, 2024.

(51) Int. Cl. G11C 11/408

(52) U.S. Cl. CPC G11C 11/4087

(57) ABSTRACT

In some examples, a fuse array, a mode register, or a combination thereof, is programmed to select which banks and/or rows are to be utilized in a reduced density mode of a memory device. In some examples, an additional fuse or other programmable device is used to indicate memory device is operating in a reduced density mode. The information from the fuse array, mode register, or combination thereof, is provided to an array utilization circuit, which uses the information to access the utilized portions of the memory array. In some embodiments, the array utilization circuit may map a smaller external row address space to a larger internal row address space when a memory device is in a reduced density mode.

### CROSS REFERENCE TO RELATED APPLICATION(S)

This application claims the benefit under 35 U.S.C. § 119 of the earlier filing date of U.S. Provisional Application Ser. No. 63/677,285 filed Jul. 30, 2024 the entire contents of which is hereby incorporated by reference in its entirety for any purpose.

### BACKGROUND

Memory devices, such as dynamic random access memory (DRAM) devices, have arrays of memory cells arranged into rows and columns. The array may be organized into subsections such as mats, banks, bank groups, and the like. The array may be tested for defects at one or more points during fabrication. For example, probe testing may be performed when die including the memory arrays are still coupled to a wafer. Testing may be performed after the die have been cut from the wafer, and/or after die have been packaged. If defects are detected in the array, in some cases, the die may be repaired. For example, typically, arrays are fabricated with extra rows referred to as “redundant rows.” If a “normal” row is found defective in a bank, the address assigned to that row may be reassigned to a redundant row of the bank. Thus, the die may be repaired, and the die may ship with the intended memory density. However, in some instances, there may be too many defective rows or columns, which may make it impossible to fully repair the array. This may require the die to be rejected, even if other banks or portions of the bank are still operable. This reduces revenue for memory manufacturers and increases waste. Accordingly, it would be desirable to be able to utilize memory die even if some regions of the array are defective.

### BRIEF DESCRIPTION OF THE DRAWINGS

FIG. 1 illustrates a block diagram of a memory array.

FIG. 2 illustrates a schematic block diagram of a semiconductor device in accordance with an embodiment of the present disclosure.

FIG. 3 is a table with an example implementation for programming a fuse array according to at least one embodiment of the present disclosure.

FIG. 4 illustrates block diagrams of a memory array with different configurations for word line usage according to at least one embodiment of the present disclosure.

FIG. 5 is a table with an example implementation for programming a fuse array to select which banks are utilized in a reduced density mode according to at least one embodiment of the present disclosure.

FIG. 6 is a circuit diagram of a logic circuit included in an array utilization circuit according to at least one embodiment of the present disclosure.

FIG. 7 is a circuit diagram of a row address mapping circuit according to at least one embodiment of the disclosure.

FIG. 8 is a circuit diagram of a row address mapping circuit according to at least one embodiment of the disclosure.

FIG. 9 is a table with an example implementation for programming a fuse array according to at least one embodiment of the present disclosure.

### DETAILED DESCRIPTION

Certain details are set forth below to provide a sufficient understanding of embodiments of the disclosure. However, it will be clear to one having skill in the art that embodiments of the disclosure may be practiced without these particular details. Moreover, the particular embodiments of the present disclosure described herein are provided by way of example and should not be used to limit the scope of the disclosure to these particular embodiments.

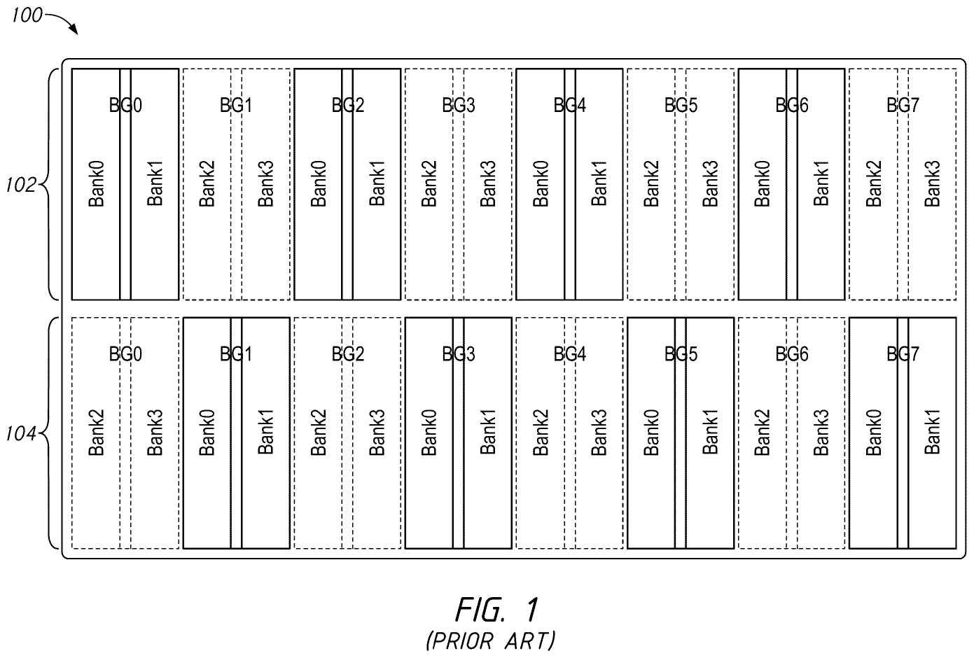

FIG. 1 illustrates a block diagram of a memory array. The memory array 100 may be a DRAM. The array may be organized into bank groups. In the example shown in FIG. 1, the array 100 is divided into eight bank groups BG0-7. Each bank group has a number of banks. In the example shown in FIG. 1, each bank group includes four banks Bank0-3. Each bank group is divided into two halves, an upper half 102 and a lower half 104, with two banks in the upper half 102 and two banks in the lower half 104. Each of the banks may have a number of rows (word lines) and columns (bit lines) with memory cells at the intersections (not shown in FIG. 1).

The memory array 100 may undergo testing to ensure all of the rows and columns of all of the banks are functional. Redundant rows and columns may be used to replace defective rows and columns to allow the memory array 100 to be repaired and shipped as a full density array. However, large portions (e.g., many word lines) of certain banks may be defective, and there may not be enough redundant rows or columns to replace the defective ones. In this situation, it may be possible to reconfigure the array to operate in a half-density mode by only utilizing half of the banks of the array. For example, an array originally intended to be sold as a 1 GB memory may be sold as 500 MB memory. This reduces financial losses for the manufacturer and reduces waste.

Currently, to utilize half-density mode, only a “checker pattern” of half-bank groups can be selected. Either the upper halves 102 of the even bank groups (BG0, BG2, BG4, BG6) and the lower halves 104 of the odd bank groups (BG1, BG3, BG5, BG7) are selected for use as indicated by the solid lines, or the upper halves 102 of the odd bank groups (BG1, BG3, BG5, BG7) and the lower halves 104 of the even bank groups (BG0, BG2, BG4, BG6) are selected for use as indicated by the dashed lines. However, this does not allow arrays to be salvaged when, for example, all of the banks of bank group BG0 are defective. Thus, even if the remaining bank groups are fully functional, the array 100 will not be able to be salvaged even though over 50% of the array 100 is functional. Accordingly, it is desirable to have more control over which portions of the array 100 are used to operate in a reduced density mode.

According to embodiments of the present disclosure, a fuse array, a mode register, or a combination thereof, may be programmed to select which banks and/or rows are to be utilized in a reduced density mode, such as a half-density mode or quarter-density mode. In some embodiments, an additional fuse or other programmable device may be used to indicate memory device is operating in a reduced density mode. The information from the fuse array, mode register, or combination thereof, may be provided to an array utilization circuit, which may use the information to access the utilized portions of the memory array. This may allow more control over which areas of the array are selected. Having more flexibility in selecting regions of the array to utilize may allow more arrays to be salvaged, reducing costs and waste.

In some embodiments, selection of a reduced density mode and/or selection of portions of the array for the reduced density mode may be performed by an end user. This may allow a memory array to continue to be utilized by the user even if the array becomes defective after use. This may reduce downtime for users, even if the reduced density memory reduces performance. For example, if a portion of an array in a server becomes defective, it may be possible to configure the array to work in a half-density mode utilizing the remaining functional portions of the array. The server may be able to operate in a “limp mode” with the reduced memory capacity until the next scheduled shutdown of maintenance of the server.

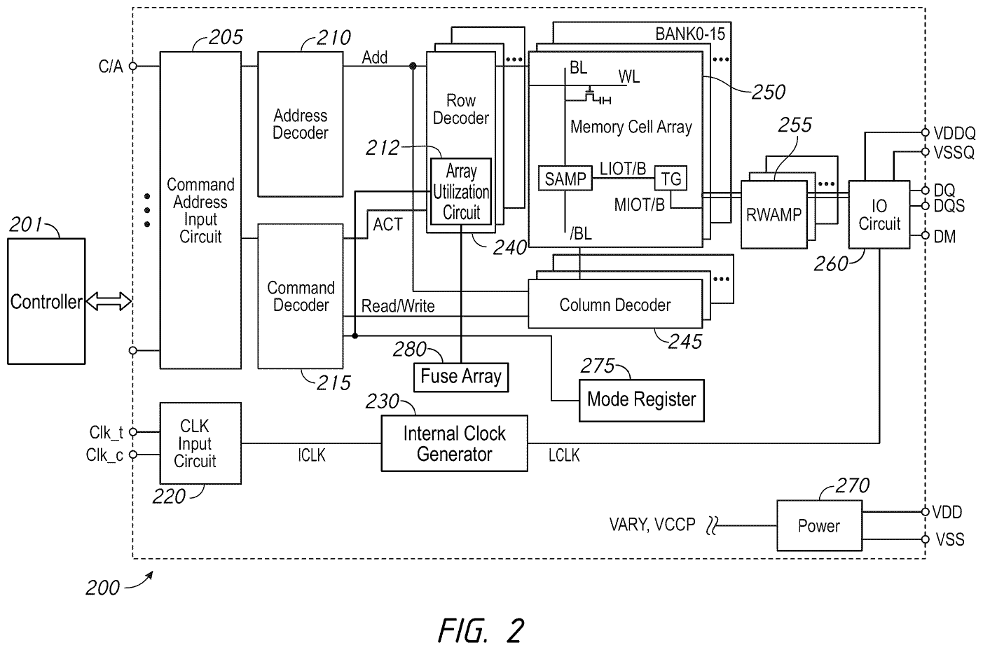

FIG. 2 illustrates a schematic block diagram of a semiconductor device in accordance with an embodiment of the present disclosure. The semiconductor device 200 includes a memory die. The memory die may include a command/address input circuit 205, an address decoder 210, a command decoder 215, a clock input circuit 220, internal clock generator 230, row decoder 240, column decoder 245, memory array 250, read/write amplifiers 255, I/O circuit 260, power circuit 270, and mode register 275.

In some embodiments, the semiconductor device 200 may include, without limitation, a dynamic random-access memory (DRAM) device, such as double data rate (DDR), low power DDR (LPDDR), or graphics DDR (GDDR), integrated into a single semiconductor chip, for example. The die may be mounted on an external substrate, for example, a memory module substrate, a mother board or the like. In some embodiments, semiconductor device 200 may be one of multiple semiconductor devices 200 (e.g., x8 or x16 devices) arranged on a dual inline memory module (DIMM). The devices may communicate with one or more controllers, such as controller 201. In other embodiments, semiconductor device 200 may be one of multiple die included in a stack, such as a high bandwidth memory (HBM) device.

The semiconductor device 200 may include a memory array 250. The memory array 250 includes a plurality of banks (BANK0-15), each bank including a plurality of word lines WL, a plurality of bit lines BL, and a plurality of memory cells MC arranged at intersections of the plurality of word lines WL and the plurality of bit lines BL. Although the memory array 250 has sixteen banks in FIG. 2, the memory array 250 may have any number of banks. The selection of the word line WL is performed by a row decoder 140 and the selection of the bit line BL is performed by a column decoder 245. Sense amplifiers (SA) are located for their corresponding bit lines BL and connected to at least one respective local I/O line (LIOT/B), which is in turn coupled to a respective one of at least two main I/O line pairs (MIOT/B), via transfer gates (TG), which function as switches. The transfer gates may be coupled to read/write amplifiers 255 that are coupled to an input/output (IO) circuit 160 that is coupled to external terminals.

The semiconductor device 200 may employ a plurality of external terminals that include address and command terminals coupled to command/address bus (C/A), clock terminals Clk_t and Clk_c, data terminals DQ, data strobe terminal DQS, and data mask terminal DM, power supply terminals VDD, VSS, VDDQ, and VSSQ. The external terminals may be used to communicate with an external device, such as controller 201. Controller 201 may be integrated with and/or in communication with a processor (not shown). In some embodiments, controller 201 may be included in a system on a chip (SoC).

The clock terminals Clk_t and Clk_c are supplied with an external clock signal and a complementary external clock signal, respectively. As used herein, a positive clock edge refers to the point where the rising true clock signal Clk_t crosses the falling bar clock signal Clk_c, while the negative clock edge indicates that transition of the falling true clock signal Clk_t and the rising of the bar clock signal Clk_c. The external clock signals may be provided by the controller 201. The external clock signals may be supplied to a clock input circuit 220. The clock input circuit 220 may receive the external clock signals to generate an internal clock signal ICLK. The internal clock signal ICLK is supplied to an internal clock generator 230, which may generate one or more internal clock signals for use by various components of the semiconductor device 200.

The power supply terminals are supplied with power supply potentials VDD and VSS. These power supply potentials VDD2 and VSS are supplied to an internal voltage generator circuit 270. The internal voltage generator circuit 270 generates various internal potentials such as VARY, VCCP, and the like based on the power supply potentials VDD and VSS. The power supply terminals are also supplied with power supply potentials VDDQ and VSSQ. These power supply potentials VDDQ and VSSQ are supplied to the input/output circuit 260. The power supply potentials VDDQ and VSSQ are typically the same potentials as the power supply potentials VDD2 and VSS, respectively. The dedicated power supply potentials VDDQ and VSSQ are used for the input/output circuit 260 so that power supply noise generated by the input/output circuit 260 does not propagate to the other circuit blocks. However, in other embodiments, VDD and VSS may be provided to the input/output circuit 260.

The command/address terminals may be supplied with a command signal from the controller 201. The command signal may be provided, via the C/A bus, to the command decoder 215 via the command/address input circuit 205. The command decoder 215 decodes the command signal to generate various internal commands that include a row command signal ACT to select a word line and a column command signal Read/Write, such as a read command or a write command.

The command/address (C/A) terminals may be supplied with an address signal from controller 201, which may in some instances be supplied with an associated command. The address signal supplied to the address terminals are transferred, via the command/address input circuit 205, to an address decoder 210. The address decoder 210 receives the address signal and decodes the address signal to provide decoded address signal ADD. The ADD signal includes a decoded bank address signal, a row address signal, and a decoded column address signal. In some embodiments, such as the one shown in FIG. 2, there may be multiple row decoders 240 and column decoders 245. Each bank of the memory array 250 may be coupled to one of the row decoders 240 and one of the column decoders 245. The decoded row address signal is provided to the row decoder 240 associated with the memory bank indicated by the bank address, and a decoded column address signal is provided to the column decoder 245 associated with the memory bank indicated by the bank address.

The semiconductor device 200 may include a fuse array 280. The fuse array 280 may include one or more fuses or antifuses that may be programmed at various stages of manufacture, packaging, or post packaging of the semiconductor device 200. While fuses, antifuses, or other programmable components may be used, examples referring to fuses will be provided herein. The fuse array 280 may be programmed to store information related to the array 250. For example, the fuse array 280 may include one or more fuses storing remapping information that indicates which rows in the array 250 have been remapped to redundant rows of the array 250. According to embodiments of the present disclosure, the fuse array 280 may include one or more fuses indicating whether the memory device is operating in a “normal” full-density mode or in a reduced density mode. The fuse array 280 may store information related to which banks and/or rows of the array 250 are utilized in a reduced density mode. In some embodiments, the fuse array 280 may include multiple fuse arrays and/or subarrays. The different fuse arrays or subarrays may be programmed to provide different types of information. For example, one portion of the fuse array 280 may be used to store information related to post-package repair operations and another portion may be used to store information related to which banks and/or rows are utilized in a reduced density mode.

In some embodiments, the row decoder 240 may include an array utilization circuit 212. The array utilization circuit 212 may receive information from the fuse array 280 indicating which banks and/or rows of the array 250 are being utilized by the semiconductor device 200. The addresses received from the address decoder 210 may be mapped to the addresses of the appropriate banks and/or rows based on the information provided by the fuse array 280.

The semiconductor device may include a mode register 275 that is programmed with information for setting various modes and features of operation for the semiconductor device 200. For example, the mode register 275 may provide parameters that allow the semiconductor device 200 to operate at different frequencies, use different burst lengths, and/or other different operating conditions. In some embodiments, mode register 275 may include multiple registers. According to embodiments of the present disclosure, the mode register 275 may further be programmed with information indicating which banks and/or rows of the array 250 are being utilized. The array utilization circuit 212 may receive information from the mode register 275 indicating which banks and/or rows of the array 250 are being utilized by the semiconductor device 200. The addresses received by the address decoder 210 from the command/address input circuit 205 may be mapped to the addresses of the appropriate banks and/or rows based on the information provided by the mode register 274.

In some embodiments, the mode register 275 may be used instead of the fuse array 280. In other embodiments, the information in the mode register 275 may supplement the information stored in the fuse array 280 regarding which banks and/or rows of the array 250 are being utilized. In some embodiments, the fuse array 280 may be used to store information on which banks and/or rows of the array 250 are being utilized when defects in the array 250 are found during testing of the array 250 during the wafer phase, die phase, and/or packaging phase. In some embodiments, the mode register 275 may be used to store information on which banks and/or rows of the array 250 are being utilized when the array 250 develops defects later (e.g., after shipment, during use by a customer, etc.). In some embodiments, the controller 201 may detect errors in the array 250 and/or receive error messages from the semiconductor device 200. The controller 201 may determine which banks and/or rows are still functional and/or which banks and/or rows are defective. The controller 201 may provide information on which banks and/or rows of the array 250 the semiconductor device 200 should continue to utilize. In some embodiments, the controller 201 may further program the mode register 275 to enter a “limp mode” where the semiconductor device 200 operates at a lower density than as originally shipped.

The information in the mode register 275 may be programmed by providing the semiconductor device 200 a mode register write command, which causes the semiconductor device 200 to perform a mode register write operation. The command decoder 215 accesses the mode register 275, and based on the programmed information along with the internal command signals provides the internal signals to control the circuits of the semiconductor device 200 accordingly. Information programmed in the mode register 275 may be externally provided by the semiconductor device 200 using a mode register read command, which causes the semiconductor device 200 to access the mode register 275 and provide the programmed information (e.g., to the memory controller 201).

Returning to the row decoder 240, when an address is provided from the command/address input circuit 205, at least a portion of the address may be provided to the array utilization circuit 212 from the address decoder 210. The array utilization circuit 212 may receive information from the fuse array 280 and/or mode register 275 related to the bank groups, banks, and/or word lines being utilized in the array 250. Based on the information from the fuse array 280 and/or mode register 275, the array utilization circuit 212 may map the received address information to a utilized row in the array 250. This utilized address may be used by the row decoder 240 to access the desired row.

Although the array utilization circuit 212 is shown as a portion of the row decoder 240 in the embodiment shown in FIG. 2, in some embodiments, the array utilization circuit 212 may be a separate component and/or all or portions of the array utilization circuit 212 may be included with the address decoder 210. In embodiments where the array utilization circuit 212 is included in the address decoder 210, some or all of the address information received from the command/address input circuit 205 may be received by the array utilization circuit 212, and the data from the fuse array 280 and/or mode register 275 may be used to generate the address signal Add output from the address decoder 210 to the row decoder 240.

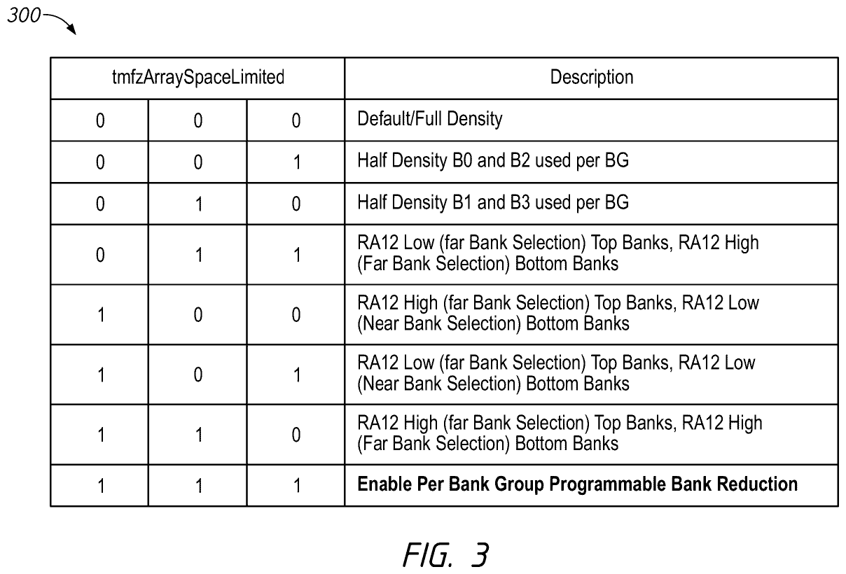

FIG. 3 is a table with an example implementation for programming a fuse array according to at least one embodiment of the present disclosure. In some embodiments, the fuse array may include fuses to store information on which banks and/or rows of the array are being utilized (tmfzArraySpaceLimited). In the example shown in FIG. 3, three fuses are utilized. However, other numbers of fuses may be used in other embodiments. In some embodiments, the fuse array may include a number of fuses for each bank group. Further, while table 300 describes certain array utilization configurations are assigned to particular programmed states of the fuses, the different configurations may be assigned to different states of the fuses. The fuses may be included in an array, such as fuse array 280 shown in FIG. 2 in some embodiments. In embodiments where a mode register is used, the states of the fuses may be replaced with states of values stored within the mode register.

The states of the fuses may be provided to an array utilization circuit (e.g., array utilization circuit 212) in an address decoder circuit (e.g., address decoder 210). The array utilization circuit may include one or more logic circuits to map received input addresses (e.g., from a memory controller) into desired output addresses to a row decoder (e.g., row decoder 240).

In a first state (“000”), the fuses may indicate that the memory array (e.g., array 250) is operating in a default and/or full density mode. For example, the array may be operating utilizing all of portions of all the banks (with perhaps the exception of a number of rows remapped to redundant rows).

The remaining states in table 300 provide for different example configurations of utilizing the array in a reduced density mode. In a reduced density mode, a subset of bank groups, banks, and/or word lines are utilized by a memory device. By subset, it is meant that less than all of the bank groups, banks, and/or word lines are utilized. In the examples provided herein, the reduced density mode is a half-density mode. However, other densities (e.g., quarter-density) may be utilized in other embodiments.

In a second state (“001”), the fuses may indicate that the memory array is utilizing the bank B0 and bank B2 of each bank group. In a third state (“010”), the fuses may indicate that the memory array is utilizing the bank B1 and bank B3 of each bank group. Thus, while FIG. 1 illustrated a “checkerboard” pattern of bank usage in the bank groups, the second and third states correspond to an “alternating stripe” pattern of bank usage.

The next four states (“011,” “100,” “101,” and “110”) correspond to usage of different regions of word lines across all of the banks and bank groups. The state of the fuses indicate whether a bit of the row address (RA) should be held low (“0”) or high (“1”). The signals from the fuses may be provided to one or more logic circuits in the array utilization circuit that cause the row address from the address decoder to be mapped to a row address with the desired state of the bit, regardless of the state of the input address bit. In the examples provided herein, the bit is RA12, which corresponds to a physical midpoint (or approximate midpoint) in the word lines of the array. However, depending on the architecture and/or address scheme of the memory array, a different bit may be overridden based on the state of the fuses in other examples.

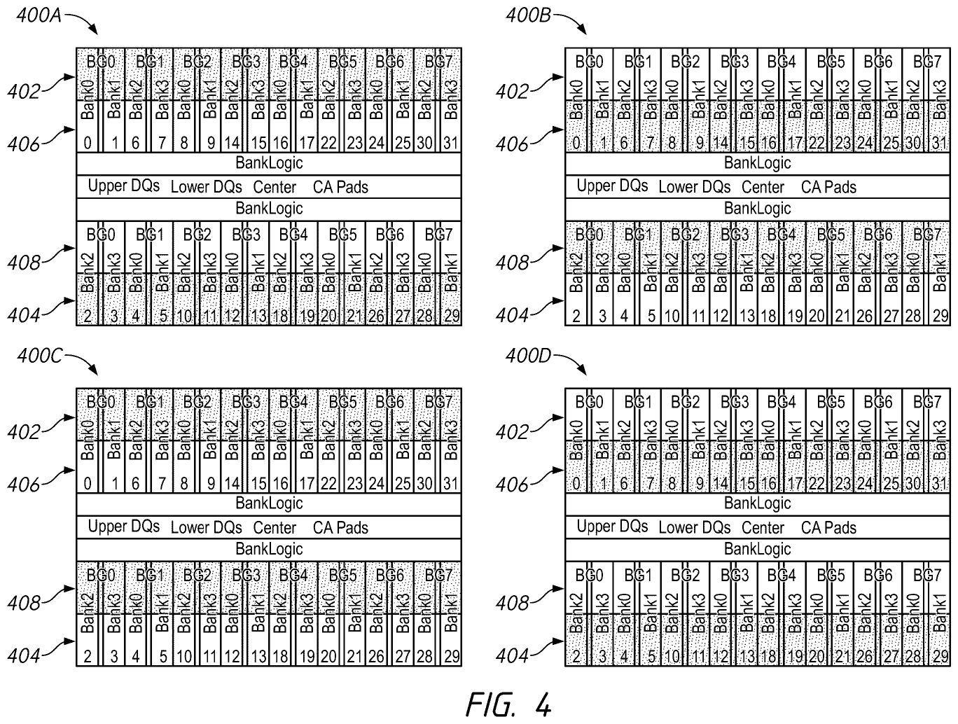

FIG. 4 illustrates block diagrams of a memory array with different configurations for word line usage according to at least one embodiment of the present disclosure. In some embodiments, the memory array 400 may be included in memory array 250 in FIG. 2. The letters after the reference numeral for the memory array 400 indicate different usage configurations of the memory array 400 according to embodiments of the disclosure.

When the fuses are in a state of “011,” the row address bit RA12 is held (e.g., fixed) low for the top banks (from the perspective of the reader) of memory array 400A, and the row address bit RA12 is held high for the bottom banks (from the perspective of the reader) of memory array 400A. This causes the word lines in regions 402 and 404 of memory array 400A to be utilized while word lines in regions 406 and 408 are not utilized. In this configuration, outer regions of the array (those regions more distant from the center) are utilized while the inner regions (those regions closer to the center) are not utilized.

When the fuses are in a state of “100,” the row address bit RA12 is held high for the top banks of memory array 400B, and the row address bit RA12 is held low for the bottom banks of memory array 400B. This causes the word lines in regions 406 and 408 of memory array 400B to be utilized while word lines in regions 402 and 404 are not utilized. In this configuration, inner regions of the array are utilized while the outer regions are not utilized.

When the fuses are in a state of “101” the row address bit RA12 is held low for both the top banks and the lower banks of memory array 400C. This causes the word lines in regions 402 and 408 to be utilized while word lines in regions 404 and 406 are not utilized. When fuses are in a state of “110” the row address bit RA12 is held high for both the top banks and the lower banks of the memory array 400D. This causes the word lines in regions 404 and 406 to be utilized while word lines in regions 402 and 408 are not utilized.

The four states of the fuses for controlling the row address bit may provide useful configurations for utilizing only portions of the memory array. During fabrication, defects often occur in clusters that may not correspond to the physical organization of banks and/or bank groups in the array. For example, the outer edges or inner edges of the array may be more affected by defects than the other. In another example, a defect in fabrication may affect several word lines in physical proximity to each other. In these situations, one of the configurations of the memory array 400A-D may allow the utilization of unaffected word lines (or regions where there are sufficient redundant word lines to correct defects) and operation in a reduced density.

Returning to FIG. 3, a final state listed in table 300 for the fuses of the fuse array (“111”) may be used to enable bank-level selection of utilized banks when operating the array in a reduced density mode. In this state, additional fuses (or registers in a mode register) may provide information on which banks are utilized. This may allow any two banks of a bank group to be utilized by the memory in a reduced density state. For example, Bank0 and Bank3 of BG0, Bank2 and Bank3 of BG1, Bank0 and Bank2 of BG2, Bank0 and Bank1 of BG3, Bank0 and Bank2 of BG4, Bank1 and Bank2 in BG5, Bank0 and Bank3 in BG6, and Bank2 and Bank3 in BG7 may be used. This is one of many possible combinations of banks that could be utilized.

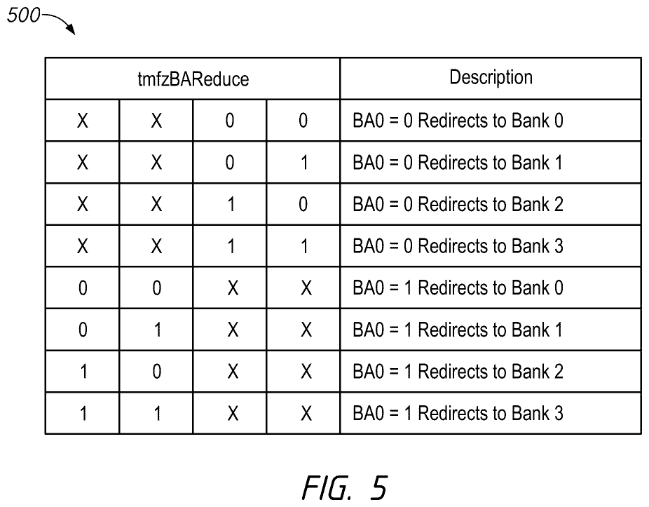

FIG. 5 is a table with an example implementation for programming a fuse array to select which banks are utilized in a reduced density mode according to at least one embodiment of the present disclosure. The fuses (tmfzBAReduce) in the fuse array may indicate which banks are utilized in a bank group based, at least in part, on a state of a bit of the bank address. In the example shown in FIG. 5, bank address bit BA0 is used, but in other examples other bits may be used, depending on the array architecture. In the example shown in FIG. 5, four fuses are utilized per bank group. However, other numbers of fuses may be used in other embodiments. Further, while table 500 describes certain array utilization configurations are assigned to particular programmed states of the fuses, the different configurations may be assigned to different states of the fuses. The fuses may be included in an array, such as fuse array 280 shown in FIG. 2 in some embodiments. In embodiments where a mode register is used, the states of the fuses may be replaced with states of values stored within the mode register.

In table 500, the two least significant bits (LSB) (right-most bits in table) indicate which banks of a bank group are utilized when the bank address bit BA0 is equal to ‘0,’ and the two most significant bits (MSB) (left-most bits in table) indicate which banks of a bank group are utilized when the bank address bit BA0 is equal to ‘1.’ The bits of tmfzBAReduce may be provided to a logic circuit of an array utilization circuit to redirect addresses for an unutilized bank of a bank group to a utilized bank of the bank group.

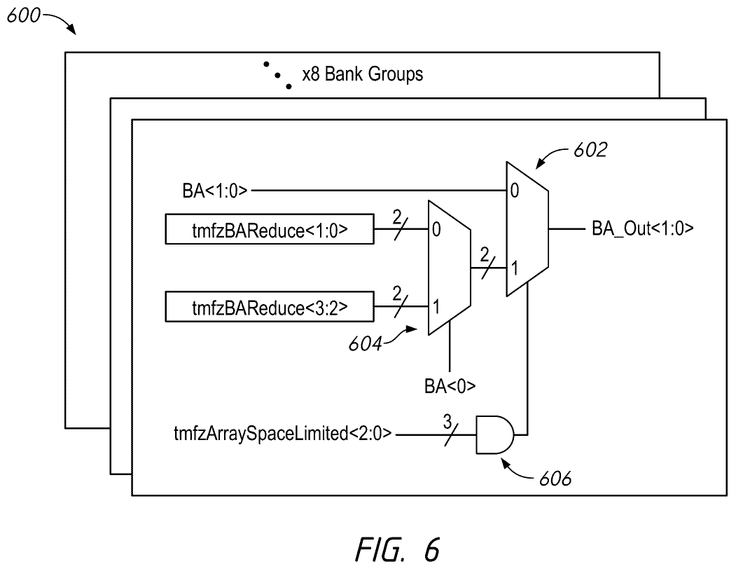

FIG. 6 is a circuit diagram of a logic circuit included in an array utilization circuit according to at least one embodiment of the present disclosure. The logic circuit 600 may be included in array utilization circuit 212 in FIG. 2 in some embodiments. In some embodiments, there may multiple logic circuits 600, one for each bank group of the memory array. In the example shown in FIG. 6, there are eight bank groups, but in other examples, other numbers of bank groups may be used.

The logic circuit includes two multiplexers (MUXes) 602 and 604, and a AND logic circuit 606. MUX 604 receives the LSB bits of table 500 tmfzBAReduce<1:0> and the MSB bits of table 500 tmfzBAReduce<3:2> as inputs, and outputs either the LSB or the MSB based on the state of BA<0>. If BA<0> equals 0, tmfzBAReduce<1:0> is provided by MUX 604. If BA<0> equals 1, tmfzBAReduce<3:2> is provided by MUX 604.

MUX 602 may receive the bank address BA<1:0> may be provided as an input and the output of MUX 604 as another input. The output of MUX 602 is determined by the output of the AND logic circuit 606. If the fuses of tmfzArraySpaceLimited are set to any state other than ‘111’ (e.g., one of the first seven states shown in table 300), the bank address BA<1:0> is output from MUX 602 as BA_Out<1:0> without modification. However, if tmfzArraySpaceLimited<2:0> is set to ‘111’ MUX 602 will provide the output of MUX 604 as BA_Out<1:0>. This will cause bank address to be altered to redirect bank addresses to the selected utilized banks as described in table 500.

The example embodiment described with reference to FIGS. 5 and 6 may allow a 50% reduced density mode for the memory array (e.g., only half the array is used). In some embodiments, tmfzBAReduce<3:2> may be set to equal tmfzBAReduce<1:0>. In these embodiments, a 25% density mode may be implemented.

The example embodiments described with reference to FIGS. 3-6 may provide greater flexibility for selecting banks to utilized for reduced density modes for memories. Further, the example embodiments may provide control over which word lines are utilized (e.g., the settings where a bit of a row address is selectively overridden) as shown in FIG. 4. While the additional flexibility for selecting regions of the array to utilize in a reduced density mode may increase the number of memory devices that may be salvaged (e.g., 1 GB memories salvaged as 500 MB memory), additional control may be desired in some applications.

According to embodiments of the present disclosure, an array utilization circuit may allow any arbitrary set of word lines to be utilized when the memory array is operating in a reduced density mode. For example, after testing the memory device, if it is determined there are too many word lines to repair using the available redundant word lines, the memory device may be salvaged by selecting any set of desired word lines for use (e.g., any 50% of the word lines for a half density mode or any 25% of the word lines for a quarter density mode). The utilized word lines may be selected by adjusting the address topography of the memory device. If needed, one or more word lines may be remapped to redundant rows using existing fuses and redundancy check circuitry.

Utilizing less than all of the word lines (e.g., half of the word lines) in the memory device may require a full address space when the memory device is operating in a reduced density mode to allow use of any non-defective word lines in the array. However, when the memory device is provided as a reduced density device, external devices, such as a memory controller, utilize a reduced address space because the external device is not aware that the memory device was originally manufactured to be a higher density. For example, on a 64 GB DDR5 component typically has a row address of R0-R17, an 18-bit row address. However, a 32 GB DDR5 component typically has a row address of R0-R16, a 17-bit row address. Accordingly, in some embodiments, a memory device operating in a reduced capacity mode may map a smaller external address space to a larger internal address space.

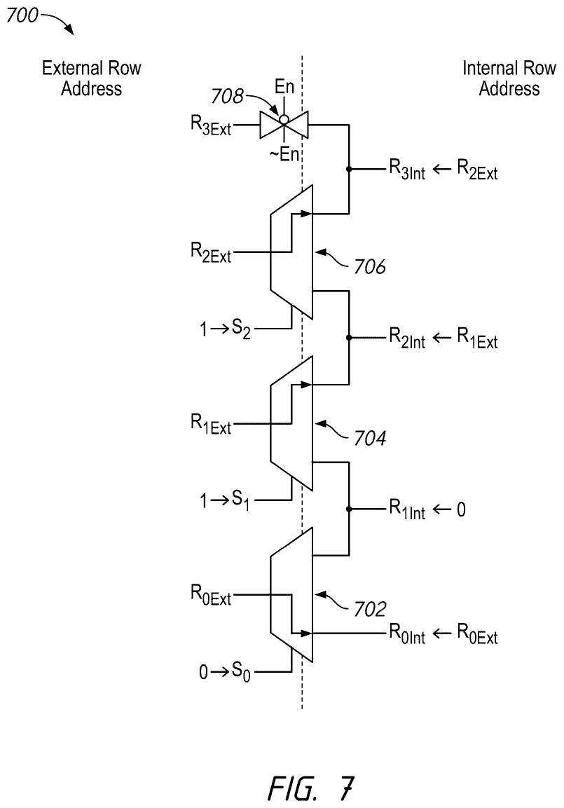

FIG. 7 is a circuit diagram of a row address mapping circuit according to at least one embodiment of the disclosure. In some embodiments, the row address mapping circuit 700 may be included in an array utilization circuit, such as utilization circuit 212 in FIG. 2. The mapping circuit 700 may include one or more demultiplexers (DEMUXes) to map the external row address to an internal row address. While the example mapping circuit 700 maps a three-bit external row address to a four-bit internal row address, the mapping circuit 700 may be expanded to accommodate longer row addresses.

In some embodiments, for a number of internal row address bits N, there may be N−1 external row address bits (R₀ to R_{N-1}) by using a number of selection signals S₀ to S_{N-1}. The number of selection signals S may equal the number of external row address bits in some embodiments. Generally speaking, any external row address bit R_{KExt} may be mapped to an internal row address bit R_{KInt} or R_{K+1Int} based on the state of a selection signal S₀-S_{(N-1)} provided to the applicable DEMUX. The signals S₀-S_{(N-1)} may be provided by fuses in a fuse array, such as fuse array 280 in FIG. 2. For any external bit R_{KExt} that is mapped to R_{K+1Int}, all more significant external address bits are also routed to their K+1 internal address bit. Due to the hardwiring of the OR operation between outputs of adjacent DMUXes, it is forbidden to set the fuses such that Sₖ←1 and Sₖ₊₁←0. Through applying the section signals S₀-S_{(N-1)} to the DMUXes, any arbitrary internal row address bit may be set to a fixed value while maintaining a contiguous row-address presentation to the external device (e.g., a memory controller).

In some embodiments, such as the one shown in FIG. 7, an input for the most significant external address bit (R_{3Ext} in the example shown in FIG. 7) may be present, even if not used, because the memory device was originally fabricated as a higher density memory device. The most significant external address bit input may be coupled to a transmission gate 708. When the memory device is operating in full density mode, each fuse Sₖ is set to ‘0’ to allow R_{KExt}→R_{KInt}.

Turning to the 4-bit row address example in FIG. 7, the external row address R_{0-2Ext} may be mapped to any arbitrary bits of the internal row address R_{0-3Ext}. However, in the example shown, internal row address bit R_{1Int} is fixed. R_{0Ext} is provided as an input to DEMUX 702, R_{1Ext} is provided as an input to DEMUX 704, and R_{2Ext} is provided as an input to DEMUX 706. R_{3Ext} is not provided when the memory device is used in the reduced memory mode. The fuses for the selection signal S [2:0] are set to ‘110’ resulting in R_{2Ext}→R_{3Int}, R_{1Ext}→R_{2Int}, R_{0Ext}→R_{0Int}, and R_{1Int} held at ‘0.’ This is mapping is illustrated by the routing arrows inside the DEMUXes 702, 704, and 706. Note that S₂ could not be set to ‘0’ as this would be a forbidden state, and both R_{1Ext} and R_{2Ext} would be mapped to R_{2Int}, creating a signal conflict.

In the embodiment shown in FIG. 7, when setting an internal row address bit to a fixed value, the fixed address bit is held at ‘0.’ However, it may be desirable to select ‘0’ or ‘1’ for the state of the fixed address bit in some applications.

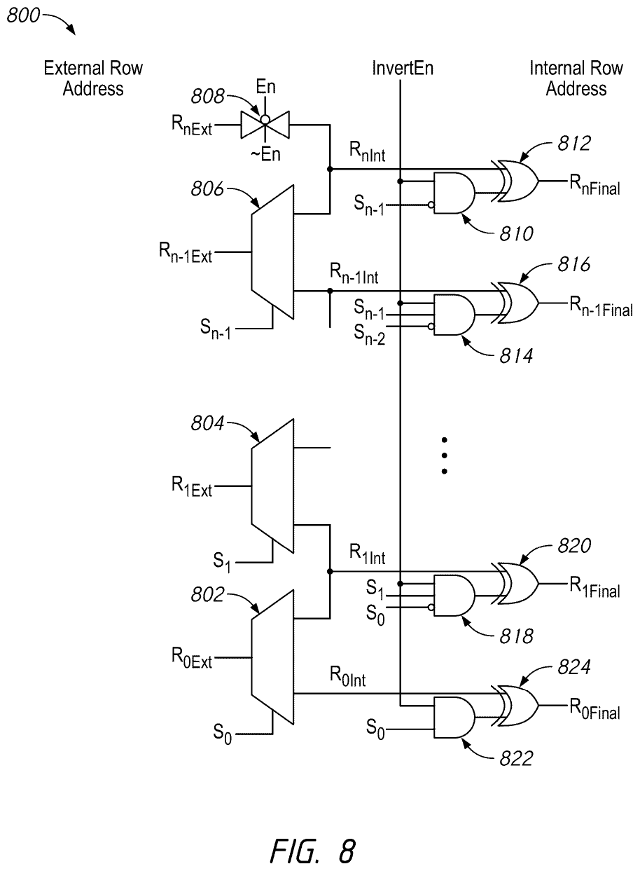

FIG. 8 is a circuit diagram of a row address mapping circuit according to at least one embodiment of the disclosure. In some embodiments, the row address mapping circuit 800 may be included in an array utilization circuit, such as utilization circuit 212 in FIG. 2. The mapping circuit 800 receives an external row address having an n−1 number of bits and map the external row address to an internal row address having an n number of bits. The mapping circuit 800 may include one or more demultiplexers (DEMUXes) to map the external row address to the internal row address, similar to the embodiment shown in mapping circuit 700. In contrast to mapping circuit 700, the mapping circuit 800 includes additional circuitry downstream from the DEMUXes to allow for selectively setting the omitted row address bit to ‘0’ or ‘1.’

The DEMUXes 802, 804, and 806 receive external row address bits R_{0Ext}, R_{1Ext}, and R_{n-1Ext} and receive select signals S₀-Sₙ₋₁. The input for a row address bit R_{nExt} may be present and coupled to a transmission gate 808 to allow an external device to provide another row address bit when the memory device is used in a full density mode. The adjacent outputs of adjacent DEMUXes are hardwired OR′d together, just as the DEMUXes shown in FIG. 7. The select signals S₀-Sₙ₋₁ may be provided by fuses in a fuse array, such as fuse array 280 and/or values stored in registers of a mode register, such as mode register 275. The external row address bits R_{0Ext}-R_{n-1Ext} may be mapped to the internal row address bits R_{0Int}-R_{nInt} based on the states of the select signals S₀-Sₙ₋₁.

The mapped internal row address bits R_{0Int}-R_{nInt} are provided to additional logic circuits 810-822. This additional logic allows selectively setting the fixed address bit to either ‘0’ or ‘1.’ Only the fixed internal row address bit is selectively inverted. The fixed bit R_{KInt} is identified by where the select signals change from ‘1’ to ‘0’ (Sₖ←1 and Sₖ₋₁←0). There is only one point where two adjacent select signals are different from one another. Otherwise, there would be a forbidden state where two external row address bits are routed to a same internal row address bit as discussed previously. Accordingly, the fixed row address bit may selectively fixed to ‘0’ or ‘1’ by the following logical expression:

$${R}_{kint} ⊕ ( InvertEn \cdot {S}_{k} \cdot \overline{{S}_{k - 1}} ) \to {R}_{kFinal} \qquad Equation ( 1 )$$

Where InvertEn is an invert enable signal that indicates whether the fixed bit should be set to ‘0’ or ‘1.’ The InvertEn signal may be provided by a fuse or a value in a register of a mode register. Equation (1) is implemented for internal row address bits R_{0Int}-R_{nInt} to generate R_{0Final} through R_{nFinal} by an AND logic circuit and an XOR logic circuit.

For “middle” row address bits (neither the LSB or MSB), the AND logic circuit receives three inputs, where one of the inputs is inverted. For example AND logic circuit 814 receives the InvertEn signal, and selection signals Sₙ₋₁ and Sₙ₋₂. Select signal Sₙ₋₂ is provided to the inverted input of the AND logic circuit 814. XOR logic circuit 816 receives R_{n-1Int} and the output of AND logic circuit 814. When R_{n-1Int} is not fixed, Sₙ₋₁ and Sₙ₋₂ are either both ‘1’ or both ‘0.’ Accordingly, regardless of the value of InvertEn, the output of the AND logic circuit 814 will be ‘0.’ Thus, the output of the XOR logic circuit 816, R_{n-1Final}, will be the value of R_{n-1Int}. When R_{n-1Int} is fixed, R_{n-1Int}=0, Sₙ₋₂=0 and Sₙ₋₁=1. If the fixed bit is set to be ‘0,’ InvertEn=0, so both inputs to the XOR logic circuit 816 will be ‘0,’ and R_{n-1Final} will be fixed to ‘0.’ If the fixed bit is set to be ‘1,’ InvertEn=1, and the output of the AND logic circuit 814 will be ‘1,’ so R_{n-1Final} provided by the XOR logic circuit 816 will be ‘1,’ inverting R_{n-1Int}. AND logic circuit 818 and XOR logic circuit 820 may operate in a similar fashion.

For the LSB (R_{0Int}), select signal S₀ and InvertEn are provided as inputs to AND logic circuit 822. R_{0Int} and the output of AND logic circuit 822 are provided to XOR logic circuit 824. If S₀=1, then all other S_{K}=1, and R_{0Int} is fixed at ‘0.’ If InvertEn is ‘1,’ the output of the AND logic circuit 822 is ‘1,’ and the output of the XOR logic circuit 824 will invert R_{0Int} to ‘1’ as R_{0Final}. If InvertEn is ‘0,’ R_{0Final} will be ‘0.’ If S₀=0, the output of the AND logic circuit 822 will be ‘0’ regardless of the state of InvertEn, and the output of the XOR logic circuit 816 will be R_{0Int} (e.g., R_{0Final}=R_{0Int}).

For the MSB (R_{nInt}), select signal Sₙ₋₁ and InvertEn are provided as inputs to AND logic circuit 810. Sₙ₋₁ is provided to an inverted input of the AND logic circuit 810. R_{nInt} and the output of AND logic circuit 810 are provided to XOR logic circuit 812. If Sₙ₋₁=0, then R_{nInt} is fixed at ‘0.’ If InvertEn is ‘1,’ the output of the AND logic circuit 810 is ‘1,’ and the output of the XOR logic circuit 812 will invert R_{nInt} to ‘1’ as R_{nFinal}. If InvertEn is ‘0,’ R_{nFinal} will be ‘0.’ If S₀=1, the output of the AND logic circuit 810 will be ‘0’ regardless of the state of InvertEn, and the output of the XOR logic circuit 812 will be R_{nInt} (e.g., R_{nFinal}=R_{nInt}).

As discussed the select signals S₀-Sₙ₋₁ indicate which bit of the internal row address is fixed in order to map the external row address to the internal row address. Generally, to fix a bit R_{KInt}, all the select bits from S_{K} to Sₙ₋₁ are set to ‘1’ and all bits S₀ to S_{K-1} are set to ‘0.’ This may be implemented by programming a fuse for each select signal. For a 64 GB DDR5 die, there would be 17 fuses per bank to provide signals for S₀-S₁₆, or alternatively, 17 registers per bank if a mode register is used. An additional fuse or register is needed to implement the InvertEn if the embodiment shown in FIG. 8 is implemented. However, in addition to having a fuse for each bit of the row address, there is a risk that one or more fuses may be programmed incorrectly, leading to invalid states where more than one external row address bit is mapped to a same internal row address bit.

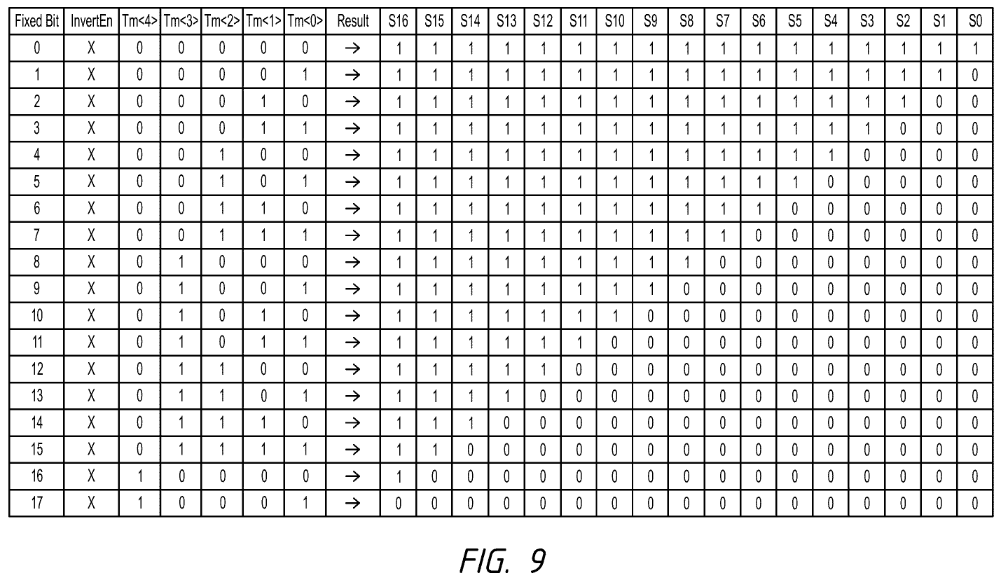

FIG. 9 is a table with an example implementation for programming a fuse array according to at least one embodiment of the present disclosure. The first column of table 900 indicates the of the internal row address to be fixed. The second column of the table represents the fuse for setting the InvertEn signal. Columns Tm<4:0> indicate the states of fuses that can be used to encode the states of the select signals shown in the columns labeled S<16:0>. The fuses Tm<4:0> may be included in a fuse array, such as fuse array 280. In the example shown in table 900, five fuses per bank can be used to support row-address busses up to 32 bits in size, plus a sixth fuse for setting the InvertEn signal if the embodiment shown in FIG. 8 is implemented. Using encoding may reduce the number of fuses needed per bank to implement select signals S<16:0> and/or reduce the risk of an invalid state for select signals S<16:0> being programmed into the fuse array.

The signals from the fuses may be provided to one or more logic circuits in an array utilization circuit (e.g., array utilization circuit 212) that decode the information provided by the fuses to provide the select signals S<16:0> to the row address mapping circuit (e.g., mapping circuit 700 and/or mapping circuit 800). While encoding select signals S<16:0> may require more logic circuits in the array utilization circuit, in some applications, the overall layout requirements may be less than when more fuses are utilized. In some applications, the layout requirements for the logic circuits in the array utilization circuit may be greater than using more fuses. However, there may be more space available in the array utilization circuit than in the fuse array. Accordingly, whether more fuses are used or more logic circuits are used to implement the select signals may be based on the area constraints of a particular memory device.

The apparatuses, systems, and methods disclosed herein may be used to select which banks and/or rows (e.g., word lines) of an array are to be utilized when a memory device is operating in a reduced density mode (e.g., 25%, 50% density). The apparatuses, systems, and methods disclosed herein may allow more control over which areas of the array are selected. Having more flexibility in selecting regions of the array to utilize may allow more arrays to be salvaged, reducing costs and waste.

From the foregoing it will be appreciated that, although specific embodiments of the disclosure have been described herein for purposes of illustration, various modifications may be made without deviating from the spirit and scope of the disclosure. Accordingly, the disclosure is not limited except as by the appended claims.

What is claimed is:

1. An apparatus comprising:
a memory array comprising a plurality of banks each comprising a plurality of word lines;
a fuse array comprising a plurality of fuses configured to store information indicating a subset of the plurality word lines utilized in a reduced density mode; and
an array utilization circuit configured to receive the information from the fuse array and cause a row decoder to access individual word lines of the subset in the reduced density mode.

2. The apparatus of claim 1, wherein the information from the fuse array is configured to cause the array utilization circuit to hold a bit of a row address comprising multiple bits at a value corresponding to the subset of the plurality of word lines.

3. The apparatus of claim 1, wherein the information from the fuse array is configured to cause the array utilization to circuit to hold a bit of a row address comprising a plurality of bits at a first value corresponding to a first portion of the subset of the plurality of word lines included in a first subset of the plurality of banks and hold the bit of the row address at a second value corresponding to a second portion of the subset of the plurality of word lines included in a second subset of the plurality of banks,
wherein the first value and the second value are different, and the first subset of the plurality of banks and the second subset of the plurality of banks are different.

4. The apparatus of claim 1, wherein the plurality of fuses is further configured to store information indicating a subset of the plurality of banks utilized in the reduced density mode.

5. The apparatus of claim 4, wherein the array utilization circuit comprises a logic circuit configured to change a bank address based on the information indicating the subset of the plurality of banks.

6. The apparatus of claim 1, wherein the plurality of fuses is further configured to store information indicating whether a memory device including the memory array is operating in a full density mode or the reduced density mode.

7. The apparatus of claim 1, wherein the subset of the plurality of word lines comprises half of the plurality of word lines in the reduced density mode.

8. An apparatus comprising:
a memory array comprising a plurality of word lines;
an array utilization circuit configured to map an external row address to an internal row address; and
a fuse array comprising a plurality of fuses configured to store first information indicating which bits of the external row address should be mapped to which bits of the internal row address and second information indicating whether the memory array is utilized in a full density mode or a reduced density mode.

9. The apparatus of claim 8, wherein the external row address comprises a first number of bits and the internal row address comprises a second number of bits greater than the first number of bits.

10. The apparatus of claim 8, wherein the array utilization circuit comprises a plurality of demultiplexers configured to receive the external row address and map the bits of the external row address to the bits of the internal row address.

11. The apparatus of claim 10, wherein the first information from the fuse array is provided to the plurality of demultiplexers.

12. The apparatus of claim 9, wherein a bit of the internal row address is held at a first value by the array utilization circuit.

13. The apparatus of claim 12, wherein the plurality of fuses is further configured to store third information indicating whether the bit of the internal row address should be held at ‘0’ or ‘1.’

14. The apparatus of claim 13, wherein the array utilization circuit comprises a logic circuit to hold the first value or invert the first value to a second value based on the third information.

15. The apparatus of claim 9, wherein the memory array comprises a plurality of banks, and the plurality of fuses comprises a fuse corresponding to each bit of the external row address for each of the plurality of banks to store the first information.

16. The apparatus of claim 9, wherein the memory array comprises a plurality of banks and the plurality of fuses comprises a set of fuses encoding the first information for each of the plurality of banks.

17. The apparatus of claim 16, wherein the array utilization circuit comprises a logic circuit for decoding the first information from the set of fuses.

18. An apparatus comprising:
a memory array comprising a plurality of banks each comprising a plurality of word lines;
a mode register comprising a plurality of registers configured to store information indicating a subset of the plurality word lines utilized in a reduced density mode; and
an array utilization circuit configured to receive the information from the mode register and cause a row decoder to access individual word lines of the subset in the reduced density mode.

19. The apparatus of claim 18, wherein the mode register further comprises a register configured to store information indicating whether a memory device including the memory array, the mode register, and the array utilization circuit is operating in a full density mode or the reduced density mode.

20. The apparatus of claim 18, wherein the plurality of registers are configured to be written responsive to a mode register write command provided by a controller.
